(19) United States
(12) Patent Application Publication
(10) Pub. No.: US 2024/0057460 A1
(43) Pub. Date: Feb. 15, 2024

(54) OLED DISPLAY MODULE AND OLED DISPLAY DEVICE

(71) Applicant: Shenzhen China Star Optoelectronics Semicondustor Display Technology Co., Ltd., Shenzhen, Guangdong (CN)

(72) Inventor: Jiejie WU, Shenzhen (CN)

(21) Appl. No.: 17/638,239

(22) PCT Filed: Jan. 20, 2022
(86) PCT No.: PCT/CN2022/072876

§ 371 Date: Feb. 25, 2022

(30) Foreign Application Priority Data
Jan. 10, 2022 (CN) 202210022637.5

(51) Int. Cl. H10K 59/80; H10K 77/10

(52) U.S. Cl. CPC H10K 59/8794; H10K 77/111; H10K 2102/311

(57) ABSTRACT

An OLED display module and an OLED display device are provided. The OLED display module is supported with the thermal conductive layer and the metal tensile layer so the supporting layer works. The thermal conductive layer is disposed between the metal tensile layer and the backplate, which can speed up the heat dissipation of the OLED display module. Besides, a material having a thermal conductivity of a thermal conductivity greater than stainless steel is arranged one of the thermal conductive layer and the metal tensile layer, further speeding up the heat dissipation of the OLED display module. The bending performance of the OLED display module is improved, the bending failure is reduced, and the heat-dissipation and bending effects are balanced.

### FIELD OF THE DISCLOSURE

The present disclosure relates to a display technology, and more particularly, to a display panel and an electronic device.

### BACKGROUND

An organic light-emitting diode (OLED) display device is widely used owing to some advantages such as self-illumination, low power consumption, and thinness. To not do damage on an OLED display device of the related art and to improve heat dissipation of the OLED display device of the related art, a plurality of film layers, such as backplate, a supporting plate, and a buffer material, are arranged in the OLED display device of the related art. However, the backplate and the supporting plate used in the related art make the thickness of the OLED display device be greater, causing the OLED display device to be creased or broken during folding. The number of film layers are reduced to enhance the bending effect and specifically, stainless steel is used as a supporting material. However, the OLED display module in such a design is poorer in heat dissipation. As the size of the screen of the OLED display device increases, the heating of the OLED display device is serious, and uneven temperature obviously affects the display effect.

Therefore, the OLED display device of the related art fails to deal with the technical problem of how to balance heat dissipation and bending.

### SUMMARY

### Technical Problem

An object of the present disclosure is to propose an OLED display module and an OLED display device to deal with the problem about the OLED display device of the related art, that is, how to balance heat dissipation and bending.

### Technical Solution

According to an embodiment of the present disclosure, an organic light-emitting diode (OLED) display module includes an OLED display panel, a backplate arranged at a side of the OLED display panel, a thermal conductive layer arranged at a side of the backplate away from the OLED display panel, and a metal tensile layer arranged at a side of the thermal conductive layer away from the backplate. One of the thermal conductive layer and the metal tensile layer is made of a material having a thermal conductivity greater than a thermal conductivity of stainless steel.

In some embodiments, the thermal conductive layer comprises a first adhesive layer. A material of the first adhesive layer comprises an adhesive material and a thermal conductive material doped in the adhesive material. The material of the metal tensile layer comprises a material with the thermal conductivity in a horizontal direction greater than the thermal conductivity of the stainless steel in a horizontal direction and a material with the thermal conductivity in a vertical direction greater than the thermal conductivity of the stainless steel in a vertical direction.

In some embodiments, a material of the metal tensile layer comprises one or more of a ferrous nickel alloy, an aluminum alloy, a copper alloy, a titanium alloy, and a silver alloy.

In some embodiments, the thermal conductive layer comprises a second adhesive layer and a coating layer. The coating layer is arranged between the second adhesive layer and the metal tensile layer. The thermal conductivity of the coating layer is greater than the thermal conductivity of the stainless steel.

In some embodiments, a material of the second adhesive layer comprises the adhesive material and the thermal conductive material doped in the adhesive material. The thermal conductivity of the thermal conductive material is greater than the thermal conductivity of the stainless steel.

In some embodiments, the thermal conductive layer comprises a third adhesive layer, a thermo-sensitive layer, and a fourth adhesive layer. The thermo-sensitive layer is arranged between the third adhesive layer and the fourth adhesive layer. The fourth adhesive layer is arranged between the thermo-sensitive layer and the metal tensile layer. The thermal conductivity of the thermo-sensitive layer is greater than the thermal conductivity of the stainless steel.

In some embodiments, a first opening is formed on the thermo-sensitive layer; the width of the first opening is greater than the arc length corresponding to the bending radius of the OLED display panel.

In some embodiments, a second opening is formed on the third adhesive layer; the second opening is arranged opposite to the first opening; a projection of the second opening on the fourth adhesive layer overlaps a projection of the first opening on the fourth adhesive layer.

In some embodiments, a filler material is arranged in both of the first opening and the second opening. The rigidity of the filler material is less than the rigidity of the third adhesive layer.

In some embodiments, the metal tensile layer comprises a plurality of holes; the plurality of holes are disposed in an array on the metal tensile layer.

In some embodiments, the metal tensile layer comprises a bending portion and a supporting portion, arranged outside the bending portion. The bending portion is arranged at a bending area of the OLED display panel correspondingly. A projection area of the bending portion on the backplate is greater than or equal to an area of the bending portion. The hole is disposed in an array on the bending portion.

In some embodiments, the metal tensile layer comprises holes disposed in a plurality of rows. The adjacent holes in different rows overlap in the projection side of the metal tensile layer; the adjacent holes in the different rows are cross-over disposed with the projection on one side of the metal tensile layer.

According to another embodiment of the present disclosure, an organic light-emitting diode (OLED) display device includes a driving chip and an OLED display module. The OLED display module includes an OLED display panel, a backplate arranged at a side of the OLED display panel, a thermal conductive layer arranged at a side of the backplate away from the OLED display panel, and a metal tensile layer arranged at a side of the thermal conductive layer away from the backplate. One of the thermal conductive layer and the metal tensile layer is made of a material having a thermal conductivity greater than a thermal conductivity of stainless steel.

In some embodiments, the thermal conductive layer comprises a first adhesive layer. A material of the first adhesive layer comprises an adhesive material and a thermal conductive material doped in the adhesive material. The material of the metal tensile layer comprises a material with the thermal conductivity in a horizontal direction greater than the thermal conductivity of the stainless steel in a horizontal direction and a material with the thermal conductivity in a vertical direction greater than the thermal conductivity of the stainless steel in a vertical direction.

In some embodiments, a material of the metal tensile layer comprises one or more of a ferrous nickel alloy, an aluminum alloy, a copper alloy, a titanium alloy, and a silver alloy.

In some embodiments, the thermal conductive layer comprises a second adhesive layer and a coating layer. The coating layer is arranged between the second adhesive layer and the metal tensile layer. The thermal conductivity of the coating layer is greater than the thermal conductivity of the stainless steel.

In some embodiments, a material of the second adhesive layer comprises the adhesive material and the thermal conductive material doped in the adhesive material. The thermal conductivity of the thermal conductive material is greater than the thermal conductivity of the stainless steel.

In some embodiments, the thermal conductive layer comprises a third adhesive layer, a thermo-sensitive layer, and a fourth adhesive layer. The thermo-sensitive layer is arranged between the third adhesive layer and the fourth adhesive layer. The fourth adhesive layer is arranged between the thermo-sensitive layer and the metal tensile layer. The thermal conductivity of the thermo-sensitive layer is greater than the thermal conductivity of the stainless steel.

In some embodiments, a first opening is formed on the thermo-sensitive layer; the width of the first opening is greater than the arc length corresponding to the bending radius of the OLED display panel.

In some embodiments, a second opening is formed on the third adhesive layer; the second opening is arranged opposite to the first opening; a projection of the second opening on the fourth adhesive layer overlaps a projection of the first opening on the fourth adhesive layer.

### Advantageous Effect

The present disclosure proposes an OLED display module and an OLED display device. The OLED display module includes an OLED display panel, a backplate arranged at a side of the OLED display panel, a thermal conductive layer arranged at a side of the backplate away from the OLED display panel, and a metal tensile layer arranged at a side of the thermal conductive layer away from the backplate. One of the thermal conductive layer and the metal tensile layer is made of a material having a thermal conductivity greater than a thermal conductivity of stainless steel. The present disclosure is supported with the thermal conductive layer and the metal tensile layer so the supporting layer works. The thermal conductive layer is disposed between the metal tensile layer and the backplate, which can speed up the heat dissipation of the OLED display module. Besides, a material having a thermal conductivity of a thermal conductivity greater than stainless steel is arranged one of the thermal conductive layer and the metal tensile layer, further speeding up the heat dissipation of the OLED display module. Because the metal tensile layer is disposed on one side of the backplate away from the OLED display panel, the bending performance of the OLED display module is improved, the bending failure is reduced, and the heat-dissipation and bending effects are balanced.

### BRIEF DESCRIPTION OF THE DRAWINGS

To describe the technical solutions in the embodiments of this application more clearly, the following briefly introduces the accompanying drawings required for describing the embodiments. Apparently, the accompanying drawings in the following description show merely some embodiments of this application, and a person of ordinary skill in the art may still derive other drawings from these accompanying drawings without creative efforts.

FIG. 1 illustrates a conventional organic light-emitting diode (OLED) display device.

FIG. 2 illustrates a schematic diagram of an OLED display module according to a first embodiment of the present disclosure.

FIG. 3 illustrates a schematic diagram of an OLED display module according to a second embodiment of the present disclosure.

FIG. 4 illustrates a schematic diagram of an OLED display module according to a third embodiment of the present disclosure.

FIG. 5 illustrates a schematic diagram of an OLED display module according to a fourth embodiment of the present disclosure.

FIG. 6 illustrates a schematic diagram of an OLED display module according to a fifth embodiment of the present disclosure.

FIG. 7 illustrates an OLED display module according to a first embodiment of the present disclosure.

FIG. 8 illustrates an OLED display device according to another embodiment of the present disclosure.

### DETAILED DESCRIPTION OF THE EMBODIMENTS

To help a person skilled in the art better understand the solutions of the present disclosure, the following clearly and completely describes the technical solutions in the embodiments of the present invention with reference to the accompanying drawings in the embodiments of the present invention. Apparently, the described embodiments are a part rather than all of the embodiments of the present invention. All other embodiments obtained by a person of ordinary skill in the art based on the embodiments of the present invention without creative efforts shall fall within the protection scope of the present disclosure.

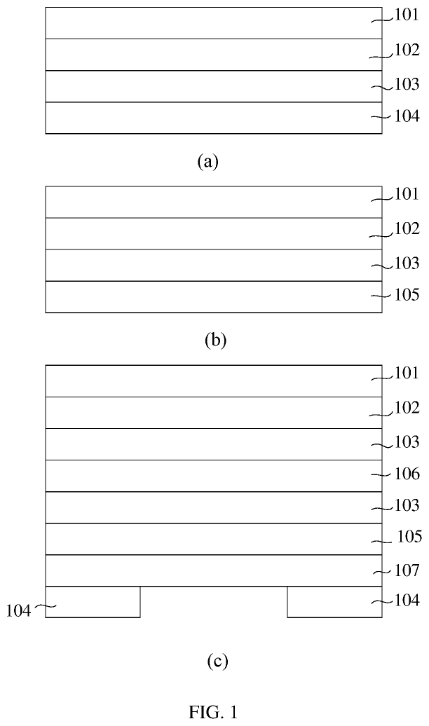

As illustrated in FIG. 1(a), an organic light-emitting diode (OLED) display device includes an OLED display panel 101, a backplate 102, an adhesive layer 103, and a heat-dissipation layer 104. The heat of the OLED display device is dissipated by the heat-dissipation layer 104. Since the heat-dissipation layer 104 is easily broken, the flexible bending performance is poor. As the thickness of the heat-dissipation layer 104 is less, the stiffness and flatness of the OLED display device is further reduced. Such a structure is generally suitable for the rigid OLED display device, which can achieve heat-dissipation capacity when the OLED display device is not bent.

As illustrated in FIG. 1(b), the adhesive layer 103 and the metal layer 105 are arranged in the backplate 102. The metal layer 105 is generally made from stainless steel so the stiffness and flatness of the metal layer 105 is better and the bending performance of the metal layer 105 reaches a certain degree. However, due to the low thermal conductivity of stainless steel (stainless steel as a metal layer in a common product including SUS304, SUS301, NM15M series, etc., the thermal conductivity is less than 20 W/(M*K)) and the heat-dissipation of the structure is worse. Such a structure is generally applicable to small-size and flexible OLED display device or a low-power flexible OLED display device with a middle size or below.

As illustrates in FIG. 1(c), a foam layer 106, a metal layer 105, and a heat-dissipation layer 104 in the backplate 102. Every one of the foam layer 106, the metal layer 105, and the heat-dissipation layer 104 is connected through the adhesive layer 103. The structure has better stiffness and flatness and has functions of bending and heat dissipation. However, the heat-dissipation layer 104, which is arranged below, has an ordinary heat-dissipation effect since the thickness of the film layer is greater. And the film layer is prone to breakage when it is folded so the structure is generally suitable for a small-size and flexible OLED product and applied to an inner folding product.

The OLED display device in the related art fails to balance heat dissipation and bending because the OLED display device in the related art is dissipated by multiple film layers or is supported by minor film layers.

The present disclosure proposes an OLED display module and an OLED display device to deal with the above-mentioned problem of how to balance heat dissipation and bending.

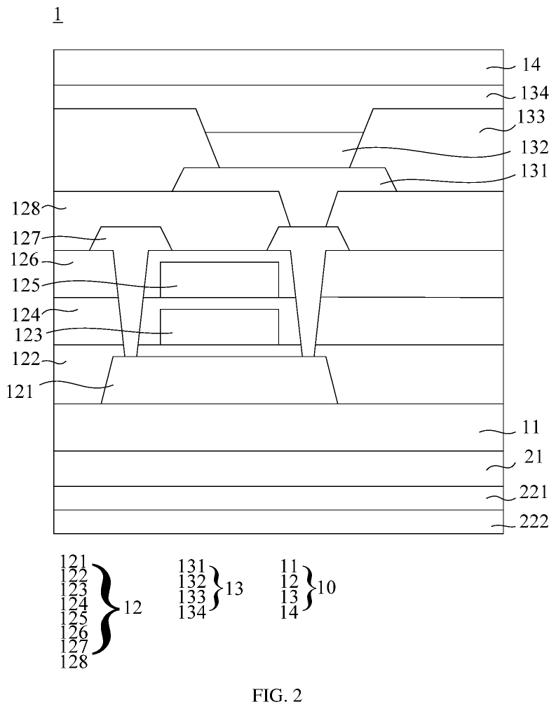

As FIG. 2 illustrates, an OLED display module is proposed by the embodiment of the present disclosure. The OLED display module 1 includes an OLED display panel 10, a backplate 21, a thermal conductive layer 221, and a metal tensile layer 222. The OLED display panel 10 is disposed on one side of the OLED display panel 10. The thermal conductive layer 221 is disposed on side of the backplate 21 away from the OLED display panel 10. The metal tensile layer 222 is disposed on one side of the thermal conductive layer 221 away from the backplate 21. One or more of the thermal conductive layer 221 and the metal tensile layer 222 includes a material of which the thermal conductivity is greater than the thermal conductivity of stainless steel.

The embodiment of the present disclosure proposes an OLED display module. The present disclosure is supported with the thermal conductive layer and the metal tensile layer so the supporting layer works. The thermal conductive layer is disposed between the metal tensile layer and the backplate, which can speed up the heat dissipation of the OLED display module. Besides, a material having a thermal conductivity of a thermal conductivity greater than stainless steel is arranged one of the thermal conductive layer and the metal tensile layer, further speeding up the heat dissipation of the OLED display module. Because the metal tensile layer is disposed on one side of the backplate away from the OLED display panel, the bending performance of the OLED display module is improved, the bending failure is reduced, and the heat-dissipation and bending effects are balanced.

Too many film layers may increase the thickness of the OLED display module and worsen the heat-dissipation effect of the OLED display module. The thermal conductive layer 221 includes a first adhesive layer. The material of the first adhesive layer includes an adhesive material and a thermal conductive material doped in the adhesive material.

The material made from the metal tensile layer 222 includes a material with the thermal conductivity in a horizontal direction greater than the thermal conductivity of stainless steel in a horizontal direction and with thermal conductivity in a vertical direction greater than the thermal conductivity of stainless steel in a vertical direction. The first adhesive layer and the metal tensile layer 222 are taken as supporting layers and the heat-dissipation material is doped in the first adhesive layer so that the first adhesive layer can quickly export the energy of the OLED display panel and distribute the energy to the whole plane. The material chosen to be made from the metal tensile layer 222 is a material with the thermal conductivity in a horizontal direction and in the vertical direction both greater than the thermal conductivity of stainless steel and can dissipate heat rapidly. The metal tensile layer 222 is arranged in the outermost layer of the OLED display module. When the OLED display panel is bent, it is possible to avoid breakage for the OLED display module. Due to the thickness of the display module in this design is less, the bending property of the OLED display module is further enhanced.

The material of the first adhesive layer includes an acrylic adhesive and a thermal conductive material doped in the acrylic adhesive. The energy produced by the OLED display panel is output faster and the heat produced by the OLED display panel is dissipated by using an acrylic adhesive as an adhesive and thermal conductive material doped in the acrylic adhesive. In other words, the heat dissipation effect of the OLED display panel improved.

The acrylic acid-based adhesive selects a thermal conductivity greater than or equal to 0.8 watts/(meter*Kelvins) (W/(M*K)) and the peel strength greater than 10 Newton/inches (N/IN). The first adhesive layer is formed by a material with greater thermal conductivity to improve the thermal conductivity of the first adhesive layer.

The thermal conductive materials include one or more of aluminum, copper, silver, gold, aluminum oxide, boron nitride, graphite, graphene, and nanocarbon. The thermal conductivity of the thermal conductive material is greater. Compared to the original adhesive layer, the energy can be quickly exported and distributed on the plate and then the heat is dissipated when the OLED display panel generates the energy.

The mass fraction of the thermal conductive material ranges from 30% to 70% so the thermal conductive material in the first adhesive layer is relatively high, and the thermal conductive material can be uniformly distributed in the respective areas of the first adhesive layer. When the OLED display panel generates energy, the whole surface of the first adhesive layer may be thermally conductive and the rate of the heat conductivity is greater. Overall, the heat-dissipation rate of the OLED display panel is improved.

The thickness of the first adhesive layer ranges from 50 to 100 micrometers (am). The thickness of the OLED display module does not increase and the bending performance of the OLED display module maintains good because the thickness of the first adhesive layer is less.

The material of the metal tensile layer 222 includes one or more of a ferrous nickel alloy, an aluminum alloy, a copper alloy, a titanium alloy, and a silver alloy. The metal tensile layer 222 is made from the above-mentioned materials. Firstly, these materials ensure the bending performance of the OLED display module. Secondly, these materials can improve the heat-dissipation effect of the OLED display module. So the OLED display module of the present disclosure balances heat dissipation and bending performances.

The tensile strength of the metal tensile layer 222 is greater than 500 Mega Pascal (MPa). When the tensile strength of the metal tensile layer 222 is greater than 500 MPa, the metal tensile layer 222 can meet the bending property of the OLED display module and the tensile strength of the metal tensile layer 222 may be further improved. Further, the bending performance of the OLED display module becomes better so as to prevent the metal tensile layer 222 from breakage when the OLED display module is bent.

The thermal conductivity of the metal tensile layer 222 is greater than or equal to 100 W/(M*K) in a horizontal direction and a vertical direction. The thermal conductivity of stainless steel is about 10 to 20 W/(M*K). The metal tensile layer 222 with a thermal conductivity of 100 W/(M*K) is chosen to increase the thermal conductivity and heat dissipation effect of the metal tensile layer 222. In this way, the metal tensile layer 222 balances heat dissipation and bending effects.

The thickness of the metal tensile layer 222 is less than 200 μm. If the thickness of the metal tensile layer 222 is less than 200 μm, the bending performance of the OLED display module is satisfied, the thickness of the metal tensile layer 222 is further reduced, and the bending performance of the OLED display module is further improved. If the thickness of the metal tensile layer 222 is too small, the stiffness of the metal tensile layer 222 is too insufficient to support the OLED display panel. If the thickness of the metal tensile layer 222 is too great, the bending performance of the OLED display module is obviously affected. Therefore, the thickness of the metal tensile layer 222 ranges from 50 to 150 μm.

The supporting layer of the OLED display module may include only the first adhesive layer and the metal tensile layer 222 so that the thickness of the OLED display module is less. Compared with the OLED display device of the related art, the material of the first adhesive layer is changed and the thermal conductive material is doped in the first adhesive layer in the present disclosure. The thermal conductive effect of the first adhesive layer is added, followed by changing the material of the metal tensile layer 222. Therefore, the metal tensile layer 222 has better tensile strength and better heat-dissipation performance, and further, the metal tensile layer 222 and the first adhesive layer has better bending and heat-dissipation properties. In sum, the heat-dissipation performance and bending performance of the OLED display module both are balanced.

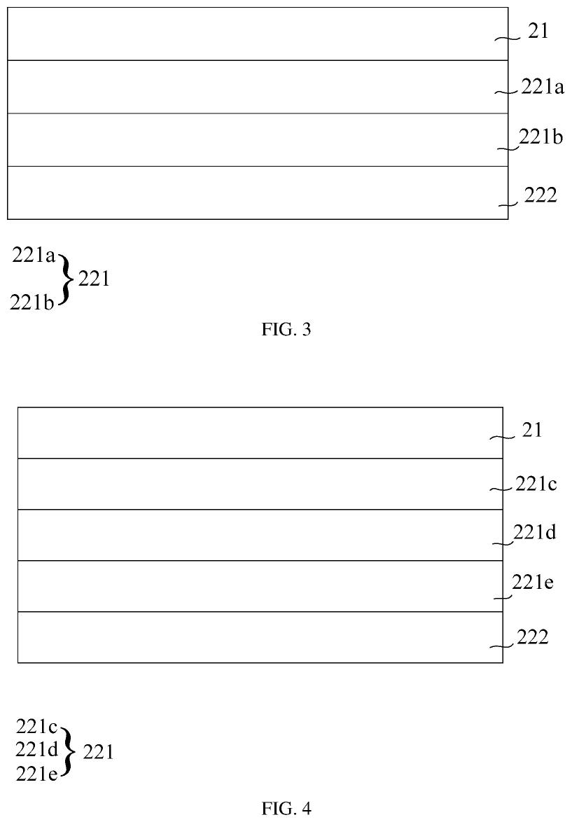

The technical issues for the OLED display device of the related art are that the OLED display device of the related art fail to balance the heat-dissipation and bending properties. In a preferred embodiment of the present disclosure, as illustrated in FIG. 3, the OLED display device includes the second adhesive layer 221a and the coating 221b. The coating 221b is disposed between the second adhesive layer 221a and the metal tensile layer 222. The thermal conductivity of the coating 221b is greater than the thermal conductivity of stainless steel. The arrangement of the coating layer makes the heat conductivity of the coating be greater than the thermal conductivity of stainless steel. The coating layer is arranged near the OLED display panel and can quickly export and release the energy of the OLED display panel. Besides, owing to metal tensile layer 222, the OLED display module can be bent normally, thereby balancing the heat-dissipation effect and the bending effect of the OLED display module.

The material of the second adhesive layer includes an adhesive material and a thermal conductive material doped in the adhesive material. The thermal conductivity of the thermal conductive material is greater than the thermal conductivity of stainless steel. The thermal conductive material is doped into the second adhesive layer to make the second adhesive layer further speed up the rate of the export of the energy of the OLED display panel and make the energy of the OLED display panel be conducted to the second adhesive layer and the coating layer quickly and release and conduct the energy to the metal tensile layer 222 such that the OLED display module can balance the heat dissipation effect and the bending property.

The material of the second adhesive layer includes a acrylic adhesive and a thermal conductive material, which is doped in the acrylic adhesive.

Preferably, the material of the second adhesive layer is the same as the material of the first adhesive layer. When the second adhesive layer is formed by a material with a greater thermal conductivity, the thermal conductive effect of the second adhesive layer is better.

The thermal conductive materials include one or more of aluminum, copper, silver, gold, aluminum oxide, boron nitride, graphite, graphene, and nanocarbon. The thermal conductivity of the thermal conductive material is greater. Compared to the original adhesive layer, the energy can be quickly exported and distributed on the plate and then the energy is dissipated when the OLED display panel generates the energy.

The mass fraction of the thermal conductive material ranges from 30% to 70% so the thermal conductive material in the second adhesive layer is relatively high, and the thermal conductive material can be uniformly distributed in the respective areas of the second adhesive layer. When the OLED display panel generates energy, the whole surface of the second adhesive layer can be thermal conductive and the rate of the heat conductivity is greater. Overall, the heat-dissipation rate of the OLED display panel is improved.

The second adhesive layer ranges from 50 to 100 μm. The thickness of the second adhesive layer is less to prevent the thickness of the OLED display module from increasing, and the bending performance of the OLED display module maintains good.

The thermal conductivity of the coating layer is greater than 1000 W/(M*K). A material with a large thermal conductivity is used to form a coating layer so that the energy rapidly spreads from the whole surface of the coating layer to the film layer below and that the heat of the coating layer is dissipated faster.

The thermal conductivity of the coating layer is greater than 1000 W/(M*K) in a horizontal direction. The thermal conductivity of the coating layer in a horizontal direction is greater so the energy can be quickly conducted through the whole surface to enhance the heat-dissipation effect.

The material of the coating layer includes one or more of graphite, nanocarbon, carbon nanotubes, and graphene. The above-mentioned materials for the coating layer may accelerate heat conductivity and heat dissipation. Besides, the bending performance of these materials is better, which is good for avoiding breakage.

The thickness of the coating layer ranges from 5 to 20 μm. The thickness of the coating layer is less to prevent an increase in the thickness of the OLED display module due to the thickness of the coating layer and to maintain the bending property of the OLED display module good. In addition, the coating layer makes the heat-dissipation effect of the OLED display module better.

The tensile strength of the metal tensile layer 222 is greater than 500 MPa. When the tensile strength of the metal tensile layer 222 is greater than 500 MPa, the metal tensile layer 222 may meet the bending property of the OLED display module and the tensile strength of the metal tensile layer 222 may be further improved. Further, the bending performance of the OLED display module becomes better so as to prevent the metal tensile layer 222 from breakage when the OLED display module is bent.

A material of the metal tensile layer 222 includes stainless steel and an alloy of iron and nickel. The heat is conducted by the second adhesive layer and the coating layer. The heat is dissipated by the second adhesive layer, the coating layer, and the metal tensile layer 222. The material of the metal tensile layer 222 may be made from stainless steel. However, the thermal conductive layer 221 and metal tensile layer 222 of the present embodiment still balances heat-dissipation and bending effects. Additionally, the present embodiment is not limited thereto, and the material of the metal tensile layer 222 may include a metal tensile material according to the above examples, for example, a ferrous nickel alloy, an aluminum alloy, a copper alloy, a titanium alloy, and a silver alloy, to further improve heat-dissipation effect. The detail is not provided here.

In the present embodiment, the OLED display module includes a second adhesive layer, a coating layer, and a metal tensile layer 222 and the material of the metal tensile layer 222 does not change. Compared to the structure of the OLED display device of the related art, owing to the design of the second adhesive layer and the coating layer, the heat-dissipation effect of the OLED display module is improved. Further, the material of the metal tensile layer 222 is chosen to be the material as introduced above to improve the heat-dissipation effect. Thereby, the thermal conductive layer 221 and the metal tensile layer 222 have the better bending and heat-dissipation properties. It not only balances the heat-dissipation performance and bending performance of the OLED display module but also lessen the thickness of the film layer in such a structural design.

The OLED display module fails to balance the heat-dissipation and bending effects. As illustrated in FIG. 4, the thermal conductive layer 221 includes a third adhesive layer 221c, a thermo-sensitive layer 221d, and a fourth adhesive layer 221e in a preferred embodiment of the present disclosure. The thermo-sensitive layer 221d is disposed between the third adhesive layer 221c and the fourth adhesive layer 221e. The fourth adhesive layer 221e is disposed between the thermo-sensitive layer 221d and the metal tensile layer 222. The thermal conductivity of the thermo-sensitive layer 221d is greater than the thermal conductivity of stainless steel. The heat-dissipation effect of the OLED display module is improved owing to the thermo-sensitive layer 221d arranged near the OLED display panel. In addition, the thermal conductivity of the thermo-sensitive layer 221d greater than the thermal conductivity of stainless steel further improves the heat-dissipation effect of the OLED display module. The metal tensile layer 222 is arranged outside the OLED display module so that the OLED display module can have better bending performance. In sum, the OLED display module balance the heat-dissipation and bending effects.

The material of the third adhesive layer 221c includes an acrylic adhesive, and the third adhesive layer 221c can be an adhesive that comes with a thermo-sensitive layer 221d.

The material of the third adhesive layer 221c includes an acrylic adhesive with a peel-off force greater than 10 N/IN to prevent the third adhesive layer 221c from being peeled off so worse binding among the different layers does not happen.

The thickness of the third adhesive layer 221c is greater than 5 μm and the thickness of the third adhesive layer 221c is less than one-half of the thickness of the thermal layer so that the thickness of the third adhesive layer 221c can reach a certain degree to bond the adjacent two film layers tight and to avoid the thickness of the OLED display module from enlarging.

The material of the fourth adhesive layer 221e includes an acrylic adhesive with a peel-off force greater than 10 N/IN, such as an optical transparent adhesive.

The thickness of the fourth adhesive layer 221e ranges from 20 to 150 μm.

The tensile strength of the metal tensile layer 222 is greater than 500 MPa. When the tensile strength of the metal tensile layer 222 is greater than 500 MPa, the metal tensile layer 222 may meet the bending property of the OLED display module and the tensile strength of the metal tensile layer 222 may be further improved. Further, the bending performance of the OLED display module becomes better so as to prevent the metal tensile layer 222 from breakage when the OLED display module is bent.

The material of the metal tensile layer 222 may be chosen as stainless steel or an aluminum alloy introduced in the above-mentioned embodiment. The present embodiment is not limited thereto, and the material of the metal tensile layer 222 may chosen according to practical situations. For example, the material of the metal tensile layer 222 is not changed to facilitate the production of the OLED display module. Another preferred embodiment is that an aluminum alloy is chosen as a metal tensile material to improve heat-dissipation effect.

The detail is not provided here.

The thickness of the metal tensile layer 222 may be the thickness of the metal tensile layer 222 as introduced above, so that it is possible to improve the bending performance of the OLED display module when the OLED display panel is supported. The detail will not be provided here.

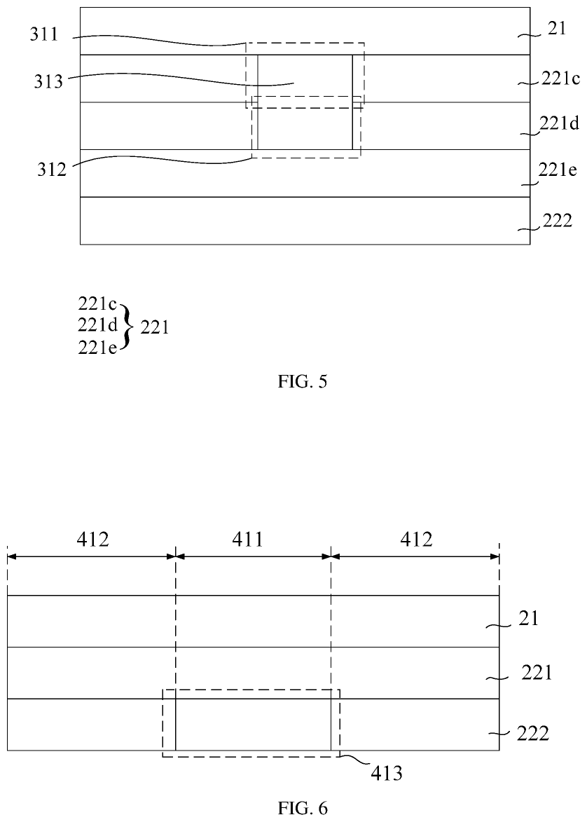

The bending performance of the thermo-sensitive layer 221d of the related art is poorer. In a preferred embodiment, as illustrates in FIG. 5, a first opening 312 is formed on a thermo-sensitive layer 221d. The width of the first opening 312 is greater than the arc length corresponding to the bending radius of an organic light-emitting diode (OLED) display panel. Because the first opening 312 on the thermo-sensitive layer 221d is formed, the thermo-sensitive layer 221d does not affect the OLED display panel to be normally bent when the bending OLED display module is bent. In other words, the bending performance of the OLED display module is improved.

As illustrated in FIG. 5, a second opening 311 is formed on the third adhesive layer 221c. The second opening 311 is arranged opposite to the first opening 312, and a projection of the second opening 311 on the fourth adhesive layer 221e overlaps a projection of the first opening 312 on the fourth adhesive layer 221e. Owing to the second opening 311 formed on the third adhesive layer 221c, the projection of the second opening 311 overlaps the projection of the first opening 312 so the bending stress of the OLED display module is reduced and the bending performance of the OLED display module is enhanced when the OLED display module is bent.

FIG. 5 illustrates that a filler material 313 is arranged in both of the first opening 312 and the second opening 311. The rigidity of the filler material 313 is less than the rigidity of the third adhesive layer 221c. Owing to the filler material 313 arranged in both of the first opening 312 and the second opening 311, the third adhesive layer 221c and the thermo-sensitive layer 221d are flattened when being arranged. Besides, the rigidity of the filler material 313 is less than the rigidity of the third adhesive layer 221c so the bending performance of the OLED display module is further improved.

The thermal conductivity of the thermo-sensitive layer 221d in the horizontal direction or in a vertical direction is greater than 200 W/(M*K). By improving the heat-dissipation effect of the OLED display module and further increasing the thermal conductivity of the thermo-sensitive layer 221d, the heat-dissipation effect of the OLED display module is further enhanced.

A material of the thermo-sensitive layer 221d includes copper foil, aluminum foil, artificial or natural graphite, graphene and so on. The heat-dissipation effect of the OLED display module is improved after the OLED display module is made from the above-mentioned material.

The thickness of the thermo-sensitive layer 221d is less than 200 μm to prevent the thickness of the thermal layer from increasing and adding the stress of the OLED display module, and the heat-dissipation effect of the thermo-sensitive layer 221d is good. As the thickness of the thermo-sensitive layer 221d is further reduced, the bending performance of the OLED display module is further improved.

Take the present embodiment for example. To satisfy the bending radius of the OLED display module less than 5 mm and to require the bending for 100,000 times, the third adhesive layer 221c and the thermo-sensitive layer 221d are formed in an opening. The width of the opening is greater than the arc length that the curved radius of the OLED display panel corresponding to plus 0.5 mm, and the arc length is less than the arc length that the curved radius of the OLED display panel corresponding to plus 1 mm. The thermal conductivity of a material of the thermo-sensitive layer 221d is greater than 1000 W/(M*K) in a horizontal direction. The thickness of the thermo-sensitive layer 221d is less than 50 μm. The third adhesive layer 221c is a self-contained adhesive of the thermo-sensitive layer 221d with a peel-off force greater than 10 N/IN of acrylic adhesive, and the thickness of the third adhesive layer 221c is 5 μm. A material of the fourth adhesive layer 221e is with a peel-off force greater than 10 N/IN of acrylic adhesive, and the thickness of the fourth adhesive layer 221e ranges from 75 to 150 μm. Thereby, it is possible to improve the bending performance of the OLED display module.

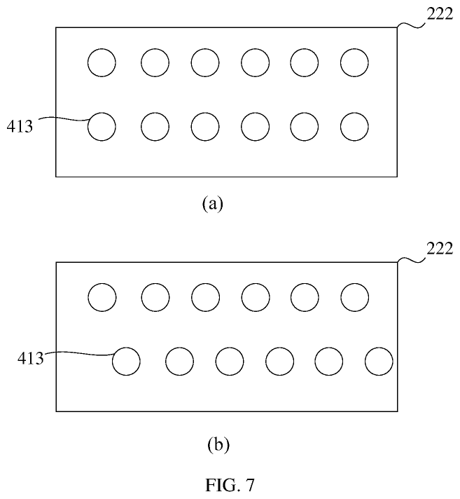

As FIG. 6 and FIG. 7 illustrate, the metal tensile layer 222 includes a plurality of holes 413. The plurality of holes 413 are disposed in an array on the metal tensile layer 222. The holes are disposed in an array by chemical etching. It is made to further improve the bending property of the metal tensile layer 222 by alleviating the local deformation due to bending or local great stress due to bending via the plurality of holes 413.

The metal tensile layer 222 includes a bending portion 411 and a supporting portion 412. The bending portion 411 is arranged on the bending area of the OLED display panel correspondingly. Moreover, the projection area of the bending portion 411 on the backplate 21 is greater than or equal to the area of the bending portion 411. The supporting portion 412 is arranged outside the bending portion 411. The plurality of holes 413 are disposed in an array on the bending portion 411. The bending portion 411 and the supporting portion 412 are arranged on the metal tensile layer 222 so that the bending portion 411 can correspond to the bending area of the OLED display panel. As the supporting effect of the metal tensile layer 222 is maintained, it is made to further improve the bending property of the metal tensile layer 222 by alleviating the local deformation due to bending or local great stress due to bending via the plurality of holes 413.

The width of the bending portion is greater than the arc length that the curved radius of the OLED display panel corresponding to plus 0.5 mm, and the arc length is less than the arc length that the curved radius of the OLED display panel corresponding to plus 1 mm.

When the holes are arranged on the whole surface, an area where no holes are not arranged ranges from 1 to 5 millimeters (mm). The area is the width of the edge of the metal tensile layer 222.

As FIG. 7(a) illustrates, the metal tensile layer 222 includes holes 413 disposed in a plurality of rows. The adjacent holes 413 in different rows overlap in the projection side of the metal tensile layer 222. Alternatively, as FIG. 7(b) illustrates, the adjacent holes 413 in the different rows are cross-over disposed with the projection on one side of the metal tensile layer 222. The holes are arranged differently with diverse bending effects and various designs of the holes 413. Specifically, the holes are cross-over arranged in different rows in the metal tensile layer 222 so that the holes 413 can lessen the bending stress when the display device is bent owing to one or more of the holes 413 arranged in each of the areas, thereby improving the bending performance of the metal tensile layer 222 and increasing the bending performance of the display device correspondingly.

The arrangement of spacing of the holes in the same rows may be equivalent or linearly changes, or the spacing of the holes in the same rows may not be linearly changes.

The shape of the hole may be, but is not limited to, circular, quadrilateral, diamond, hexagonal, and key-groove shaped.

To introduce the specific design, the metal tensile layer of different thicknesses is detailed. If the thickness of the metal tensile layer ranges from 50 to 80 μm, the metal tensile layer is made without a hole or with a hole only at the bending portion. If the thickness of the metal tensile layer ranges from 80 to 150 μm, the metal tensile layer is made without a hole or with a hole only at the bending portion. When the OLED display module is a bent display module, the holes are disposed on the whole surface of the metal tensile layer. The holes can be disposed in an array on the metal tensile layer. Specific method is as described above in the present embodiment.

The film layer has been described in detail in the present embodiment. On the condition of no conflicts in the design of each of the film layers, a preferred embodiment may adopt the design of the film layer design in other preferred embodiments. For example, the embodiment as illustrated in FIG. 4 may employ some technical features in the embodiment as illustrated in FIG. 3. The embodiment of the present disclosure is not limited to a particular technical feature of a certain embodiment. When the heat-dissipation and bending effects of the present disclosure can be implemented, the features in the different preferred embodiments can be combined. The description is not detailed here though.

As illustrated in FIG. 2, the OLED display panel includes a substrate 11, a driving circuit layer 12, a light-emitting functional layer 13, and a package layer 14.

Further, the OLED display panel includes a polarizer or a color film layer.

The driving circuit layer 12 includes an active layer 121, a first gate insulating layer 122, a first metal layer 123, a second gate insulating layer 124, a second metal layer 125, an interlayer insulating layer 126, a source/drain layer 127, and a flattened layer 128.

The light-emitting function layer 13 includes a pixel electrode layer 131, a pixel definition layer 133, a light-emitting material layer 132, and a common electrode layer 134.

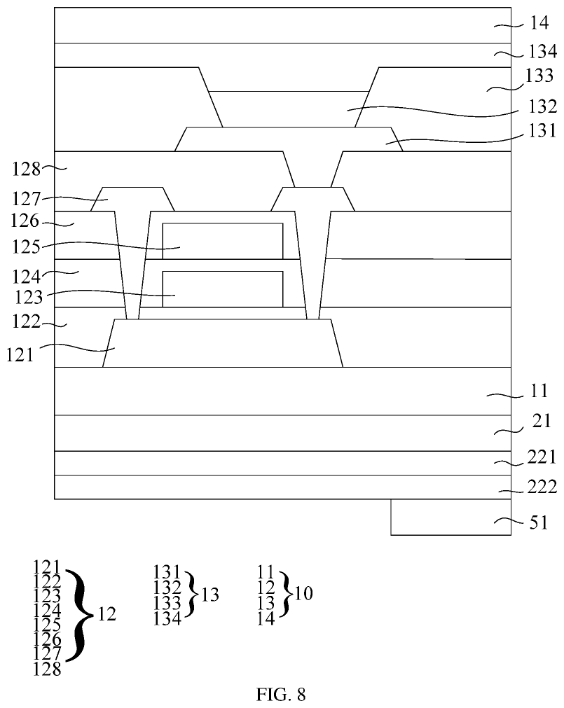

As illustrated in FIG. 8, an OLED display device is proposed by the embodiment of the present disclosure. The OLED display device includes an OLED display module 1 and a driving chip. The OLED display module 1 includes an OLED display panel 10, a backplate 21, a thermal conductive layer 221, and a metal tensile layer 222. The OLED display module 1 is disposed on one side of the OLED display panel 10. The thermal conductive layer 221 is disposed on one side of the backplate 21 away from the OLED display panel 10. The metal tensile layer 222 is disposed on one side of the thermal conductive layer 221 away from the backplate 21. The thermal conductivity of a material greater than the thermal conductivity of stainless steel is arranged in one or more of the thermal conductive layer 221 and the metal tensile layer 222.

According to the embodiment of the present disclosure, the OLED display device includes a driving chip and an OLED display module. The present disclosure is supported with the thermal conductive layer and the metal tensile layer so the supporting layer works. The thermal conductive layer is disposed between the metal tensile layer and the backplate, which can speed up the heat dissipation of the OLED display module. Besides, a material having a thermal conductivity of a thermal conductivity greater than stainless steel is arranged one of the thermal conductive layer and the metal tensile layer, further speeding up the heat dissipation of the OLED display module. Because the metal tensile layer is disposed on one side of the backplate away from the OLED display panel, the bending performance of the OLED display module is improved, the bending failure is reduced, and the heat-dissipation and bending effects are balanced.

In some embodiments, the thermal conductive layer comprises a first adhesive layer. A material of the first adhesive layer comprises an adhesive material and a thermal conductive material doped in the adhesive material. The material of the metal tensile layer comprises a material with the thermal conductivity in a horizontal direction greater than the thermal conductivity of the stainless steel in a horizontal direction and a material with the thermal conductivity in a vertical direction greater than the thermal conductivity of the stainless steel in a vertical direction.

In some embodiments, a material of the metal tensile layer comprises one or more of a ferrous nickel alloy, an aluminum alloy, a copper alloy, a titanium alloy, and a silver alloy.

In some embodiments, the thermal conductive layer comprises a second adhesive layer and a coating layer. The coating layer is arranged between the second adhesive layer and the metal tensile layer. The thermal conductivity of the coating layer is greater than the thermal conductivity of the stainless steel.

In some embodiments, a material of the second adhesive layer comprises the adhesive material and the thermal conductive material doped in the adhesive material. The thermal conductivity of the thermal conductive material is greater than the thermal conductivity of the stainless steel.

In some embodiments, the thermal conductive layer comprises a third adhesive layer, a thermo-sensitive layer, and a fourth adhesive layer. The thermo-sensitive layer is arranged between the third adhesive layer and the fourth adhesive layer. The fourth adhesive layer is arranged between the thermo-sensitive layer and the metal tensile layer. The thermal conductivity of the thermo-sensitive layer is greater than the thermal conductivity of the stainless steel.

In some embodiments, a first opening is formed on the thermo-sensitive layer; the width of the first opening is greater than the arc length corresponding to the bending radius of the OLED display panel.

In some embodiments, a second opening is formed on the third adhesive layer; the second opening is arranged opposite to the first opening; a projection of the second opening on the fourth adhesive layer overlaps a projection of the first opening on the fourth adhesive layer.

The present disclosure proposes an OLED display module and an OLED display device. The OLED display module includes an OLED display panel, a backplate arranged at a side of the OLED display panel, a thermal conductive layer arranged at a side of the backplate away from the OLED display panel, and a metal tensile layer arranged at a side of the thermal conductive layer away from the backplate. One of the thermal conductive layer and the metal tensile layer is made of a material having a thermal conductivity greater than a thermal conductivity of stainless steel. The present disclosure is supported with the thermal conductive layer and the metal tensile layer so the supporting layer works. The thermal conductive layer is disposed between the metal tensile layer and the backplate, which can speed up the heat dissipation of the OLED display module. Besides, a material having a thermal conductivity of a thermal conductivity greater than stainless steel is arranged one of the thermal conductive layer and the metal tensile layer, further speeding up the heat dissipation of the OLED display module. Because the metal tensile layer is disposed on one side of the backplate away from the OLED display panel, the bending performance of the OLED display module is improved, the bending failure is reduced, and the heat-dissipation and bending effects are balanced.

The present disclosure has been described with a preferred embodiment thereof. The preferred embodiment is not intended to limit the present disclosure, and it is understood that many changes and modifications to the described embodiment can be carried out without departing from the scope and the spirit of the disclosure that is intended to be limited only by the appended claims.

What is claimed is:

1. An organic light-emitting diode (OLED) display module, comprising:
an OLED display panel;
a backplate, arranged at a side of the OLED display panel;
a thermal conductive layer, arranged at a side of the backplate away from the OLED display panel; and
a metal tensile layer, arranged at a side of the thermal conductive layer away from the backplate;
wherein one of the thermal conductive layer and the metal tensile layer is made of a material having a thermal conductivity greater than a thermal conductivity of stainless steel.

2. The OLED display module according to claim 1, wherein the thermal conductive layer comprises a first adhesive layer; a material of the first adhesive layer comprises an adhesive material and a thermal conductive material doped in the adhesive material;
the material of the metal tensile layer comprises a material with the thermal conductivity in a horizontal direction greater than the thermal conductivity of the stainless steel in a horizontal direction and a material with the thermal conductivity in a vertical direction greater than the thermal conductivity of the stainless steel in a vertical direction.

3. The OLED display module according to claim 2, wherein a material of the metal tensile layer comprises one or more of a ferrous nickel alloy, an aluminum alloy, a copper alloy, a titanium alloy, and a silver alloy.

4. The OLED display panel according to claim 1, wherein the thermal conductive layer comprises a second adhesive layer and a coating layer; the coating layer is arranged between the second adhesive layer and the metal tensile layer; the thermal conductivity of the coating layer is greater than the thermal conductivity of the stainless steel.

5. The OLED display module according to claim 4, wherein a material of the second adhesive layer comprises the adhesive material and the thermal conductive material doped in the adhesive material; the thermal conductivity of the thermal conductive material is greater than the thermal conductivity of the stainless steel.

6. The OLED display panel according to claim 1, wherein the thermal conductive layer comprises a third adhesive layer, a thermo-sensitive layer, and a fourth adhesive layer; the thermo-sensitive layer is arranged between the third adhesive layer and the fourth adhesive layer; the fourth adhesive layer is arranged between the thermo-sensitive layer and the metal tensile layer; the thermal conductivity of the thermo-sensitive layer is greater than the thermal conductivity of the stainless steel.

7. The OLED display module according to claim 6, wherein a first opening is formed on the thermo-sensitive layer; the width of the first opening is greater than the arc length corresponding to the bending radius of the OLED display panel.

8. The OLED display module according to claim 7, wherein a second opening is formed on the third adhesive layer; the second opening is arranged opposite to the first opening; a projection of the second opening on the fourth adhesive layer overlaps a projection of the first opening on the fourth adhesive layer.

9. The OLED display module according to claim 8, wherein a filler material is arranged in both of the first opening and the second opening; the rigidity of the filler material is less than the rigidity of the third adhesive layer.

10. The OLED display panel according to claim 1, wherein the metal tensile layer comprises a plurality of holes; the plurality of holes are disposed in an array on the metal tensile layer.

11. The OLED display module according to claim 10, wherein the metal tensile layer comprises:
a bending portion, arranged at a bending area of the OLED display panel correspondingly; a projection area of the bending portion on the backplate, being greater than or equal to an area of the bending portion;
a supporting portion, arranged outside the bending portion;
the hole is disposed in an array on the bending portion.

12. The OLED display module according to claim 10, wherein the metal tensile layer comprises holes disposed in a plurality of rows; the adjacent holes in different rows overlap in the projection side of the metal tensile layer; the adjacent holes in the different rows are cross-over disposed with the projection on one side of the metal tensile layer.

13. An organic light-emitting diode (OLED) display device, comprising:
a driving chip; and
an OLED display module, comprising:
an OLED display panel;
a backplate, arranged at a side of the OLED display panel;
a thermal conductive layer, arranged at a side of the backplate away from the OLED display panel; and
a metal tensile layer, arranged at a side of the thermal conductive layer away from the backplate;
wherein one of the thermal conductive layer and the metal tensile layer is made of a material having a thermal conductivity greater than a thermal conductivity of stainless steel.

14. The OLED display device according to claim 13, wherein the thermal conductive layer comprises a first adhesive layer; a material of the first adhesive layer comprises an adhesive material and a thermal conductive material doped in the adhesive material;
the material of the metal tensile layer comprises a material with the thermal conductivity in a horizontal direction greater than the thermal conductivity of the stainless steel in a horizontal direction and a material with the thermal conductivity in a vertical direction greater than the thermal conductivity of the stainless steel in a vertical direction.

15. The OLED display device according to claim 14, wherein a material of the metal tensile layer comprises one or more of a ferrous nickel alloy, an aluminum alloy, a copper alloy, a titanium alloy, and a silver alloy.

16. The OLED display device according to claim 13, wherein the thermal conductive layer comprises a second adhesive layer and a coating layer; the coating layer is arranged between the second adhesive layer and the metal tensile layer; the thermal conductivity of the coating layer is greater than the thermal conductivity of the stainless steel.

17. The OLED display device according to claim 16, wherein a material of the second adhesive layer comprises the adhesive material and the thermal conductive material doped in the adhesive material; the thermal conductivity of the thermal conductive material is greater than the thermal conductivity of the stainless steel.

18. The OLED display device according to claim 13, wherein the thermal conductive layer comprises a third adhesive layer, a thermo-sensitive layer, and a fourth adhesive layer; the thermo-sensitive layer is arranged between the third adhesive layer and the fourth adhesive layer; the fourth adhesive layer is arranged between the thermo-sensitive layer and the metal tensile layer; the thermal conductivity of the thermo-sensitive layer is greater than the thermal conductivity of the stainless steel.

19. The OLED display device according to claim 18, wherein a first opening is formed on the thermo-sensitive layer; the width of the first opening is greater than the arc length corresponding to the bending radius of the OLED display panel.

20. The OLED display device according to claim 19, wherein a second opening is formed on the third adhesive layer; the second opening is arranged opposite to the first opening; a projection of the second opening on the fourth adhesive layer overlaps a projection of the first opening on the fourth adhesive layer.
